(19) United States
(12) Patent Application Publication
(10) Pub. No.: US 2023/0258745 A1
(43) Pub. Date: Aug. 17, 2023

(54) Magnetic Field Detection Apparatus, System, and Method

(71) Applicant: Motus Labs, LLC, Dallas, TX (US)

(72) Inventor: Carlos A. HOEFKEN, Dallas, TX (US)

(21) Appl. No.: 18/011,092

(22) PCT Filed: Jun. 24, 2021
(86) PCT No.: PCT/US21/38940

§ 371 Date: Dec. 16, 2022

Related U.S. Application Data
(60) Provisional application No. 63/043,721, filed on Jun. 24, 2020.

(51) Int. Cl. G01R 33/07

(52) U.S. Cl. CPC G01R 33/072

(57) ABSTRACT

An apparatus, system or method for magnetic flux detection, having a first collector with a set of collection points along a first edge to interact with a set of magnets, with the first collector also having a sensor point on a second edge being distal from the first edge, a second collector having a set of collection points along a first edge that interact with the set of magnets, and a third collector having a set of collection points along a first edge interacting with the set of magnets.. The second collector can also have a sensor point on a second edge that is distal to the first edge. The third collector can have a sensor point on a second edge that is distal from the first edge. The fractions of magnetic flux pass from the first sensor point and second sensor point to the third sensor point.

### CROSS-REFERENCE TO RELATED APPLICATIONS

This application is a US 371 Application from PCT/US2021/038940 filed on Jun. 24, 2021, published as WO2021/0263011 on Dec. 20, 2021, which claims the benefit of U.S. Provisional Application No. 63/043,721, filed Jun. 24, 2020, entitled “Magnetic Field Detection Apparatus, System, And Method,” the disclosure of which is hereby incorporated by reference in its entirety.

### BACKGROUND

### Technical Field

The present disclosure relates to magnetic field or flux detection. More particularly, and not by way of limitation, the present disclosure is directed to an apparatus, system, or method for increased sensitivity of a magnetic field detection device or system.

### Description of Related Art

Magnetism is one of the basic physical principles that has been known for many years. Most individuals understand that a magnet has two poles: a north pole and a south pole that are attracted to one another. If a person tries to place two magnets together with the same pole facing one another, there will be a repulsive force preventing the two magnets from coming together. The magnetic field that is distributed by a magnet can be detected through the use of sensors such as Hall effect sensors. However, these current systems are limited in their detection capabilities as well as the relation placement of the magnet(s) and a sensor. For example, the sensor must be placed within the magnetic field yet also be far enough away to avoid interference by other magnetic fields or adjacent magnets. To counter this, most devices place the sensor next to the set of magnets. However, this limits the amount of magnetic field or flux that can be detected or sensed.

Detecting the direction of the magnetic flux is used as a way to measure linear or angular position on a large number of applications, for example: robotic actuators, telescopes, antennas, etc. However, an increasing number of applications require a precision that is beyond the limit of what magnetic sensors can deliver. The typical rotary magnetic sensor is limited to about 4000 pulses per revolution, it is then very desirable to be able to increase the resolution of magnetic sensor by a device that controls, distributes, and amplifies an existing magnetic vector in such a way to increase the resolution of typical magnetic sensors.

It would be advantageous to have an apparatus, system, or method that overcomes the disadvantages of the prior art. The present disclosure provides such a system and method. Magnetic sensors, such as Hall sensors, are able to detect the intensity, magnitude, or strength of magnetic flux, while other more sophisticated magnetic sensors are able to detect the not only the intensity, but also the direction of the magnetic flux (detection of a magnetic flux vector).

### BRIEF SUMMARY

The present disclosure is related to magnetic field detection, or the detection of a magnetic flux.

Thus, in one aspect, the present disclosure is directed to a magnetic field detection apparatus or system having a first collector with a set of first collection points configured to interact with a set of magnets. The interaction allows the set of first collection points to receive or transmit a fraction of a magnetic flux generated by the set of magnets. The first collector also has a first sensor point. The apparatus or sensor includes a second collector having a set of second collection points that can interact with the set of magnets. The second collector may receive or transmit a fraction of the magnetic flux generated by the set of magnets. The second collector can also have a second sensor point. The apparatus or sensor includes a third collector having a set of third collection points for interacting with the set of magnets, by transmitting or receiving a sum of the first fraction and the second fraction of the magnetic flux to the set of magnets. The third collector can have a third sensor point. The fractions of magnetic flux may pass from the first sensor point and the second sensor point through a sensor detection area to the third sensor point.

In another aspect, the present disclosure is directed to a magnetic field detection apparatus or system including, a first collector having a set of first collection points along a first edge of the first collector, with a first sensor point on a second edge of the first collector being distal from the first edge of the first collector, a second collector having a set of second collection points along a first edge of the second collector, the second collection having a second sensor point on a second edge of the second collector that is distal from the first edge of the second collector, and a third collector having a set of third collection points along a first edge of the third collector. A third sensor point may be found on a second edge of the third collector that is distal from the first edge of the third collector. The sensor points can be equally spaced around a sensor void that is defined by the arrangement of said sensor points.

### BRIEF DESCRIPTION OF THE DRAWINGS

The novel features believed characteristic of the disclosure are set forth in the appended claims. The disclosure itself, however, as well as a preferred mode of use, further objectives and advantages thereof, will be best understood by reference to the following detailed description of illustrative embodiments when read in conjunction with the accompanying drawings, wherein:

FIG. 1 is a perspective view illustration of a magnetic field detection system.

FIG. 2 is a perspective view illustration of a magnetic detection system.

FIG. 3 is a side perspective view illustration of a magnetic detection system.

FIG. 4 is a perspective view illustration of a multi-level magnetic detection system.

FIG. 5A is a side view illustration of a magnetic detection system.

FIG. 5B is a side view illustration of a magnetic detection system.

FIG. 6A is a top view illustration of a magnet array.

FIG. 6B is a top view illustration of a magnet array.

FIG. 7A is a top view illustration of a magnetic field detection system with a rotating platform in a first position.

FIG. 7B is a top view illustration of a magnetic field detection system with a rotating platform in a second position.

FIG. 7C is a top view illustration of a magnetic field detection system with a rotating platform in a third position.

### DETAILED DESCRIPTION

Embodiments of the disclosure will now be described. This device and system of this disclosure can be used to collect magnetic flux from one or more sets of magnets, allowing for the transfer of that magnetic flux to a sensor in a manner that increases the number of pulses that can be read per revolution by a sensor to increase the number of pulses that can be read per revolution, or alternatively increase the number of revolutions of a magnetic field around a sensor. This allows for smaller movements of a moveable object to be measured through magnetic flux or field detection. There are many examples of these types of systems, such as but not limited to, rulers that have a magnifying lens, calipers that include a needle gauge for increased resolution, scales that utilized gear mechanisms and long indication needles, i.e., longer needle allows for smaller measurable steps, and air pressure gauges that use multiple sections and valves to increase the measurable resolution. However, there is still a need for similar types of systems for use with magnetic flux or fields. The present disclosure allows for the measurement of small magnetic vector increments that need to be amplified allowing typical magnetic sensors to detect the changes/values/deviations without a need for additional sets of magnets.

The magnetic detection system, apparatus, and method allow for the detection of small movements of a platform or other moveable object having one or more sets of magnets attached to it by utilizing a set of three or more collectors. Wherein at least two of the collectors have collection points that are smaller in width (where width is the surface facing the platform or movable object) than the magnets utilized for the one or more sets of magnets. By collecting fractions (ratios) of each magnet's corresponding magnetic flux and directing each of the collected magnetic fluxes to a sensor point for detection by a sensor, the sensitivity of the sensor can be increased.

A typical magnetic flux detection sensor is placed in close proximity to a magnet array that corresponds directly to the sensor detection range. For example, a 4× magnetic sensor must have a corresponding 4× magnet array. While the present disclosure allows for the use of sets of magnets arranged along a periphery of a moveable object, with the collectors measuring fractions of the magnetic flux from a plurality of magnets in each set that are then directed to a set of sensors points for each collector that surrounds the moveable object, the collectors may be moveable about a fixed object as well. The sensor points can then transfer the magnetic flux to a sensor. Therefore, the plurality of magnets allows for the sensor to receive a magnetic flux based on the desired ratio of the number of collectors and the number of magnets. For example, if there are 21 matched magnet pairs, with three collectors (in at least one embodiment, 1 full, and 2 half width collectors), and each collector has 1 sensor point, a magnetic sensor can read 20 revolutions of magnetic flux/field around the sensor points for each single full movement of a moveable object, allowing for a multiplication of twenty times the sensing range of the sensor. The collectors allow for a sensor to see each matched pair of the sets of magnets as a single movement, creating a multiplication of the sensors range or sensing ability. If the sensor can read 1000 points for each revolution of a rotating object, then the collectors allow for the sensor of the present disclosure to read 20,000 points per revolution of the rotating object.

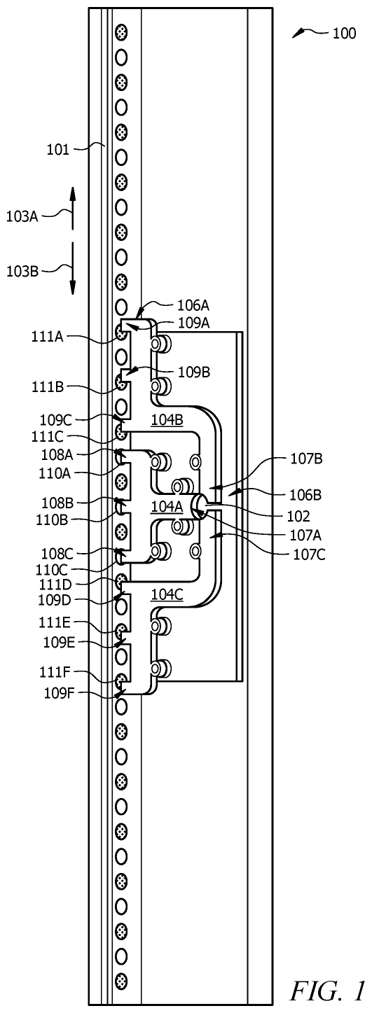

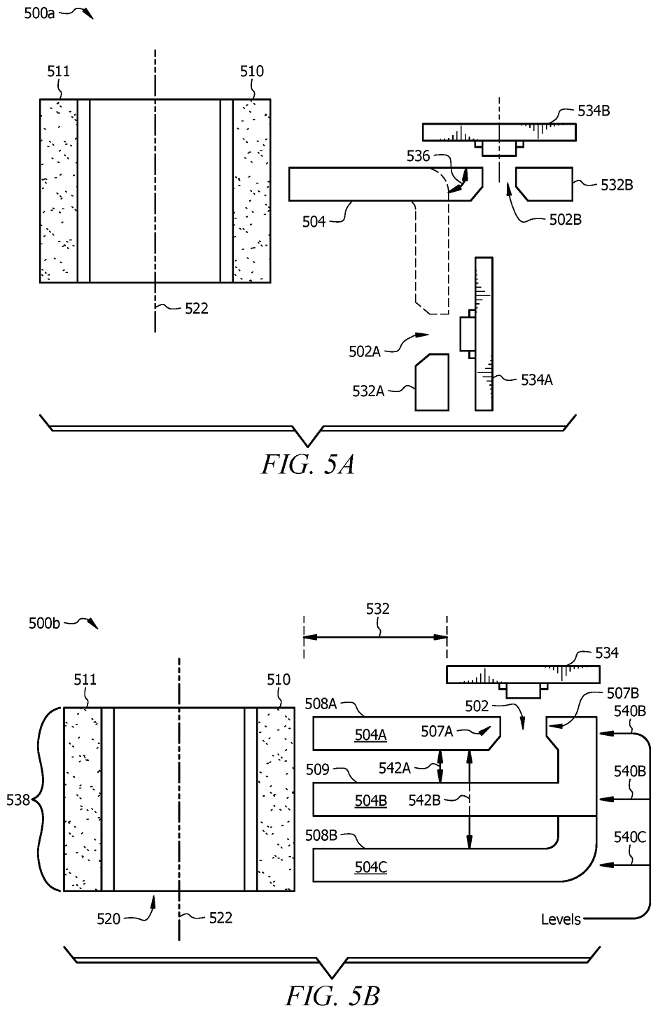

FIG. 1 is a perspective view illustration of a magnetic field detection system 100 in a linear configuration. The magnetic field detection system 100 can be utilized to increase the amount of magnetic flux or magnetic field detectable by a sensor (as seen in FIGS. 5A and 5B), and the sensor can be configured to receive the amount of magnetic flux or magnetic field at the sensor void 102, or sensor detection area 102.

In at least one embodiment, the magnetic field detection system 100, when combined with a sensor (not shown), can be utilized as an encoder for the detection of positioning of an object. The sensor void 102, in at least one example, is created by a set of collectors 104A, 104B, and 104C (collectively, collectors 104). A magnetic collector is a component able to conduct and distribute magnetic flux, in the same way as air ducts, hydraulic hoses, electrical conductors, water pipes, etc. Depending on the collector shape, the magnetic flux could be manipulated, distributed, etc. The typical magnetic conductors are made of iron, ferrite, silicon, steel, combinations thereof, or other materials with similar properties that allow for magnetic permeability. It would be understood that a set can contain one or more (in some examples, at least one) of the items associated with the set. The collectors 104 allow for the transmission of a magnetic flux from a first location at a proximal point 106A to a second location at a distal point 106B. When the amount of magnetic flux or magnetic field is increased within an area detected by a sensor, the sensitivity of the sensor may be increased by a factor determined by the amount of magnet sets or by a factor of the magnetic field or flux increase due to the sizing and/or number of collector(s) and/or collection points.

The magnetic field detection system 100 can be utilized to detect the positioning, orientation, or movement of a set of magnets or sets of magnets 110A, 110B, and 110C, or 111A, 111B, 111C, 111D, 111E, and 111F. The sets of magnets (collectively magnets 110 and 111) may interact with a magnetic core 101 that allows for the permeability of the magnetic field or flux of the magnets 110, 111 in specific directions or manners. The collectors 104 may be made of similar magnetically permeable materials such as, but not limited to iron, ferrite, silicon, steel, combinations thereof, or other materials with similar properties. The sets of magnets 110, 111 and the core 101 may move linearly in a direction parallel to the lines 103A/103B. However, the linear movement may be a rotational movement in other examples. Similarly, a non-linear or non-rotational movement may be measured with proper positioning of the collector, and/or collection points in relation to a magnetic field or flux source.

The set of collectors 104A, 104B, and 104C, in at least one example, may have a set of collection points 108A, 108B, and 108C (collectively a first set of collection points 108), and/or 109A, 109B, 109C, 109D, 109E, and 109F (collectively a second and third set of collection points 109) respectively. A first set of collection points 108A, 108B, and 108C of the first collector 104A can align with a set of magnets 110A, 110B, or 110C (with other magnets being visible in the figures and not referenced for clarity of the figures). The set of collection points 108 can align with a set of magnets that are of a first polarity. In the figure, the polarity is represented as south while it would be understood that the polarity may change, or if the set of magnets is shifted to a different position, the collection points may align with magnets of a different polarity or be partially aligned.

For example, a first collector 104A may be fully aligned with a set of magnets 110A, 110B, and 110C in a manner that allows for full transfer of magnet flux or field from or to the collector 104A. The collectors 104B and 104C can have second and third set of collection points 109A, 109B, 109C, 109D, 109E, and 109F that are partially aligned with multiple sets of magnets 111A, 111B, 111C, 111D, 111E, and 111F. The magnetic flux collected at the second and third sets of collection points 109A, 109B, 109C, 109D, 109E, and 109F is equal to the magnetic flux transmitted from the first set of collection points 108A, 108B, and 108C. The collectors 104A, 104B, and/or 104C may have corresponding sensor points 107A, 107B, and 107C that are distal from the sets of collection points 108 or 109.

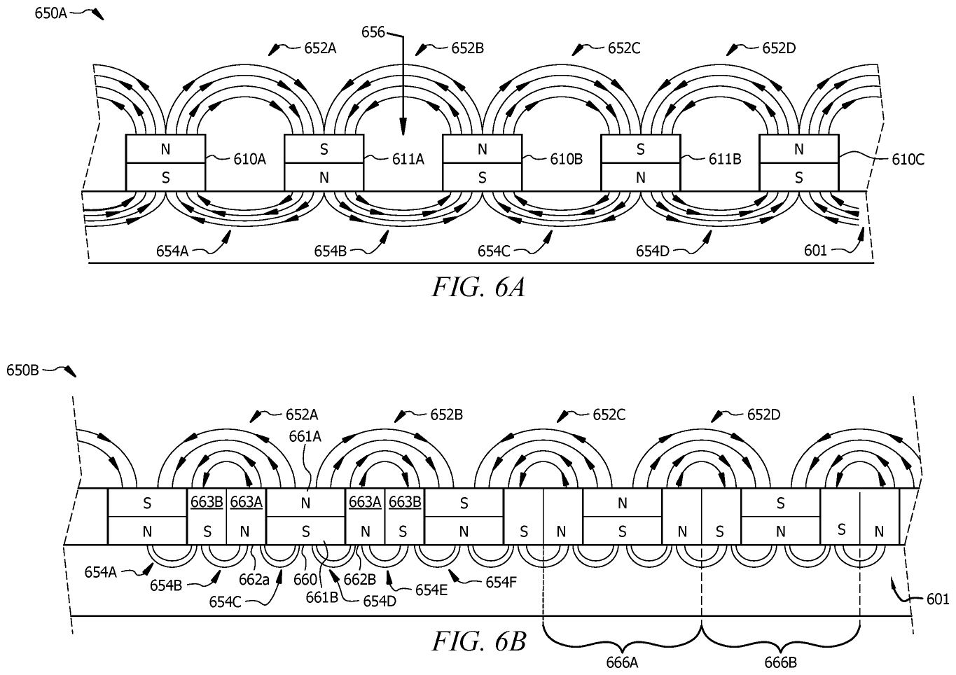

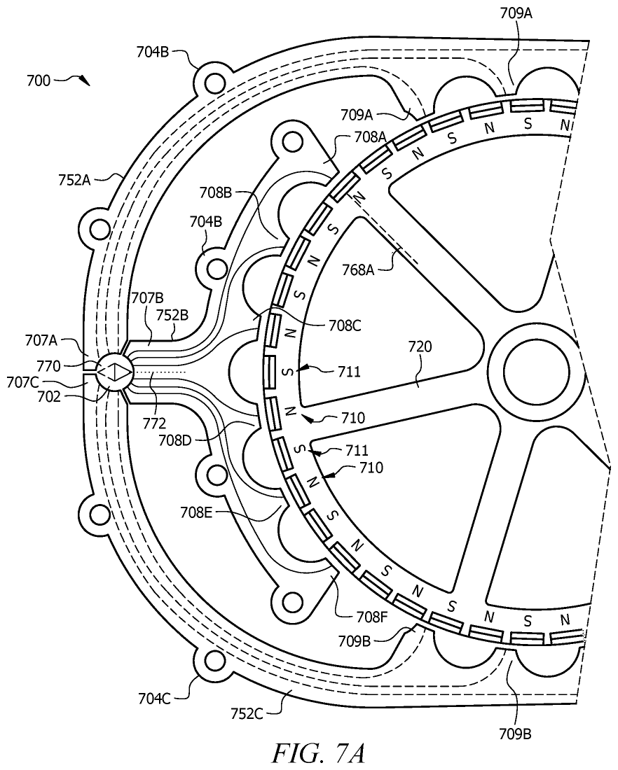

Accordingly, the magnetic field detection system 100 must have a number of receiving collection points that receive an amount of magnetic flux or field that is equal to the amount transmitted by a number of transmitting collection points. If the receiving collection points are partially aligned with a set of magnets, then the number of receiving collection points would need to be double the number of transmitting collection points if the transmitting collection points are fully aligned with a set of magnets of opposite polarity. As the sets of magnets are moved or shifted, the receiving collection points can become transmitting collection points, and transmitting collection points can become receiving collection points. The magnet flux collected by the receiving collection points can then be passed through the sensor void 102 to the set of transmitting collection points. The positioning and orientation of the magnetic field are discussed in reference to FIGS. 6A and 6B. However, it would be understood that as the sets of magnets are moved or shifted, resulting in a change in the collection and transmission of magnetic flux through the collectors, there is also a change of the magnetic flux or field within the sensor void 102 that can be measured and/or determined by a sensor. In at least one example, the ratio of portion of the collection points that align with the set(s) of magnets can be a portion of the factors that allow for the increased sensitivity. For example, if five collectors are utilized, where four of them are for transmitting and align with one-quarter of each of the corresponding magnets then the sensitivity can be increased by a corresponding amount.

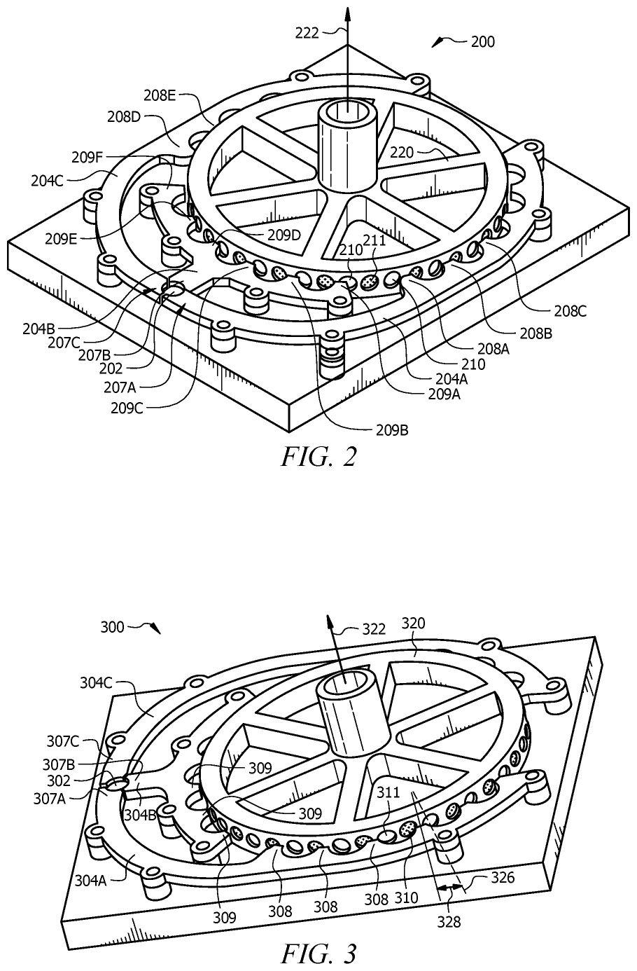

FIG. 2 is a perspective view illustration of a magnetic detection system 200 in a rotational configuration. The magnetic detection system 200 can have sets of magnets (collectively 210 and 211) that are selectively aligned with collectors 204A, 204B, and 204C. The collectors 204A, 204B, and 204C can be designed for a specified number of collection points or sensor points. Each collector can have a set of collection points 208A, 208B, 208C, 208D, 208E, and/or 209A, 209B, 209C, 209D, 209E, and/or 209F (collectively collection point sets 208 or 209) and sensor points 207A, 207B, and/or 207C (collectively sensor points 207) that allow for a magnetic flux or field to be received. The collection points 208 or 209 in at least one embodiment, may represent transmitting collection points 208 and receiving collection points 209. Alternatively, they may also by receiving collection points 208 and transmitting collection points 209.

As is known, a magnetic field or flux moves from a north polarity end to a south polarity end of a magnet. In at least one example, the receiving collection points 209 can align with a north polarity or north polarity-oriented set of magnets 210, while the transmitting collection points 208 can align or partially align with a south polarity or south polarity-oriented set of magnets 211. The magnets 210, 211 may be assembled on a rotating platform 220 that rotates about a central axis 222. As the magnets 210, 211 (by the rotation of the rotating platform 220) are rotated, the collectors 204A, 204B, and 204C may transition from receiving to transmitting, or from transmitting to receiving collectors as the magnetic fields or flux change polarity at the collection points. For example, as illustrated each collector 204A, 204B, and 204C has six individual collection points 208, or 209 that form each set, with the first set of collection points 208 being directly aligned with a set of magnets 210, and the second and third sets of collection points 209 being partially aligned (offset) with the second set of magnets 211. This allows the second and third set of collection points 209 to collect or receive a fraction of the magnetic flux or field generated by the second set of magnets 211.

The offset ratio, in at least one example, may be calculated as the number of transmitting collection points 208 divided by the total number of receiving collection points 209. The offset ratio, in other examples, may also be used to determine the number of collection points desired for each collector. The offset ratio multiplied by the total number of receiving collection points 209 would give the number of transmitting collection points 208. For example, if the desired offset ratio is 0.25 or ¼, then the number of transmitting collection points multiplied by four would give the total number of receiving collection points, that would then be divided by the number of receiving collectors. While the number of collectors 204A, 204B, 204C is illustrated as three, there could be additional collectors with each aligning or partially aligning with the sets of magnets 210, 211. As illustrated, the offset ratio would be one half, 0.5, or ½.

The collectors 204A, 204B, 204C may be constructed of a magnetically permeable material that allows for the directing, guidance, or transmission of magnetic flux or fields. In at least one embodiment, a magnetic shielding can be affixed to one or more edges of the collectors 204A, 204B, 204C to increase the concentration of the magnetic flux or fields passing through them. The collection points 208, 209 allow for the collection or transmission of magnetic flux to or from the corresponding sensor point 207. The sensor points 207 are arranged in a configuration that allows for uniform magnetic field through the sensor void 202. For example, if collector 204A is aligned with a south polarity, its sensor point 207A will also have a south polarity, while collectors 204B and 204C are configured to each pass one half of a north polarity magnetic flux, which can then magnetically engage or theoretically couple to the first collector 204A as the north polarity magnetic flux will be attracted to the south polarity magnetic flux or field. This magnetic flux or field passes through the sensor void 202 allowing a sensor configured to be coupled or placed within the sensor void 202 to pick up, measure, or determine the polarity, orientation, or magnitude of the magnetic flux or field within the sensor void 202.

Because the collectors 204A, 204B, and 204C can receive or transmit magnetic flux from multiple magnets or set of magnets 210, 211, the magnitude or intensity of the magnetic flux or field can be increased within the sensor void 202, allowing for an increase in the sensitivity of the sensor. The increase in the sensor sensitivity can be a factor of the number of collection points 208, 209 of the collectors 204A, 204B, 204C. As the amount of magnetic flux through collectors 204A, 204B, and/or 204C changes during rotation, the partially aligned collection points become fully aligned, those collection points originally fully aligned become partially aligned and the magnetic flux changes accordingly.

FIG. 3 is a side perspective view illustration of a magnetic detection system 300 in a rotational configuration. The magnetic detection system 300 can be configured to allow for the detection of a magnetic flux or field emitted by one or more sets of magnets 310 or 311. The magnetic flux or field can be collected by or directed through one or more collectors 304A, 304B, 304C (collectively, collectors 304). The collectors 304 may have a set of collection points 308 or collection points 309 at a first end of the collectors 304, while a second end of the collector 304 can have a set of sensor points 307A, 307B, or 307C (collectively, sensor points 307) for transmitting or receiving, a magnetic flux or field from another collector or set of collectors 304. The sensor points 307 can be configured to create a sensor void 302. The sensor void 302, in at least one embodiment, is configured to receive or allow for the placement of a sensor within or within close proximity of the void. In at least one example, close proximity would be within one inch of the sensor void 302 or the corresponding metric conversion. The sensor, in at least one example, may be a Hall effect sensor, magnetic field sensor, magnetic flux sensor, electric field sensor, combination thereof, or other sensors capable of detecting, calculating, or determining the orientation or direction of a magnetic field, the magnitude or intensity of a magnetic field, or other data or information regarding a magnetic field.

In at least one embodiment, the collectors 304 are arranged radially around a central axis 322. Similarly, the sets of magnets 310, or 311 in at least one embodiment may also be arranged radially around a central axis 322. While illustrated with the collectors 304 being further away from the central axis 322 than the sets of magnets 310 or 311, it would be understood that the collectors 304 and the sets of magnets 310, 311 may be arranged in any number of arrangements such as the sets of magnets 310, 311 being further away from the central axis 322 than the collectors 304. In at least one example, the sets of magnets 310, 311 may be arranged along a rotating platform 320. The rotating platform 320 may be configured like a wheel, spokes, wagon wheel, other shapes including, but not limited to, circles, ovals, polygons, or other designs that can have two or more collectors 304 arranged in close proximity, i.e., within the range of the magnetic flux or field, of the sets of magnets 310, 311. This example could be useful in a number of industrial applications, such as, but not limited to, robotics, control systems, feedback systems, audio control systems, photography systems, light control systems, vehicle control systems, aircraft control systems, motors, conveyor systems, combinations thereof, or other systems that include detection or manipulation of objects based on the position of another object.

The collectors 304 can have collection points 308 and 309. It would be understood that each collector can have one or more collection points or set of collections points aligned in any number of configurations. The alignment of the collection points 308 or 309 allows for the calculation of the amount of magnetic flux that is transferred to the sensor void 302. As the rotating platform 320 is rotated, the sets of magnets 310 and 311 are rotated, causing the magnet alignment with the collection points 308 and 309 to also change. A center line 326 through one of the magnets illustrates how a collection point 308 may be aligned with an offset amount 328. The offset amount 328 may be based on the offset ratio of the collection points 308 to the collection points 309. For example, the number of collection points 309 should equal the number of collection points 308 multiplied by the offset ratio. In some examples, there may be a need for additional collectors to allow for additional sensor points around the sensor void 302. The more sensor points along the sensor void 302, the more magnetic flux or field that can be found within the area of the sensor void 302. Additionally, the number of sensor points may also allow for increased sensitivity as the ratio of sensor points to collection points may be created to allow for a sensitivity ratio to be created for each rotational platform, the number of magnets within a set of magnets, the number of collectors, or the number of collection points.

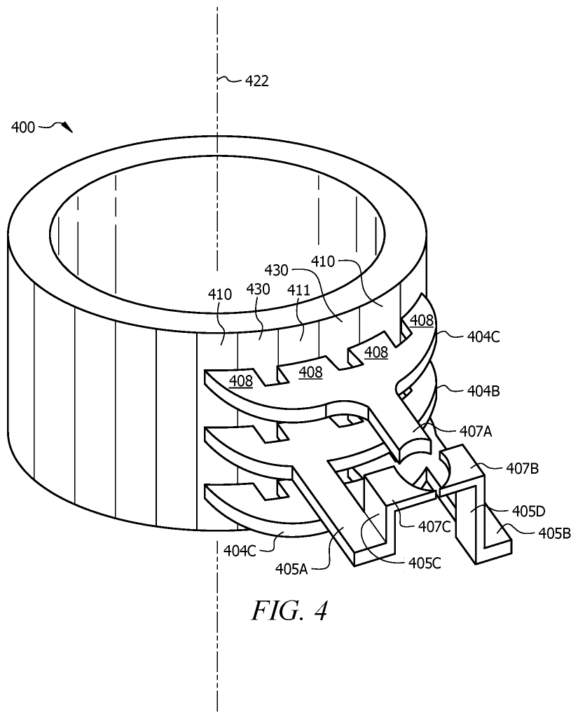

FIG. 4 is a perspective view illustration of a multi-level magnetic detection system 400 in a rotational configuration. The multi-level magnetic detection system 400 can allow for a compact magnetic detection system 400 through the use of a set of collectors 404A, 404B, and 404C (collectively collectors 404). The collectors 404 can be arranged in a vertical manner with collector 404A being a single level, collector 404B can have two levels, and collector 404C can have two levels to allow for the sensor point of each collector to be aligned on the same horizontal plane. Each of the collectors 404B and 404C may have two horizontal sections 405A and 405B, and each of the collectors 404B and 404C have two unique vertical sections 405C and 405D. The vertical sections 405C and 405D in at least one embodiment are two different lengths to allow for the vertical stacking or alignment of the collectors 404. The collectors 404 can be arranged to allow for collection points 408 on a first end of the collectors 404 and at least one sensor point 407 on a second end of the collector 404. The collectors 404 can be arranged to allow for sets of magnets 410 and 411 to interact with one or more of the collectors 404, but not all of them at the same time. For example, if there are three collectors 404A, 404B, and 404C, then one collector 404A can align with a first set of magnets 410, and the remaining two collectors 404B and 404C can align with a second set of magnets 411. The lengths 405C and 405D allow for the sensor points 407A, 407B, and 407C to be aligned in the same horizontal plane. The horizontal plane may be aligned with one of the collectors 404 or be in a separated from one or more of the collectors 404 by a specified distance by design specifications.

The sets of magnets 410 and 411 may be configured along a rotating platform 420 or other device capable of movement. For example, the rotating platform 420 may be a rotor, a stator, or a linear platform capable of making a transverse movement. The sets of magnets 410 and 411 may also be separated by a portion of non-magnetic permeable material 430. The portion of non-magnetic material 430 can include materials such as, but not limited to, plastic, wood, composites, non-magnetic metals, non-ferrous metals, combinations thereof, or other materials having similar properties. Additionally, the portion of non-magnetic permeable material 430 can provide a design-specific spacing between the sets of magnets 410 and 411. For example, the sets of magnets 410 and 411 may include a first set of magnets 410 that is configured with the north pole of the magnet facing outward from a central axis 422, while a second set of magnets 411 is configured with the south pole of the magnet facing outward from a central axis 422. The sets of magnets 410 and 411 may be arranged in an alternating fashion to create matched pairs of magnets, i.e., one magnet having a north pole facing outward next to one magnet having a south pole facing outward.

FIG. 5A is a side view illustration of a magnetic detection system 500A. The magnetic detection system 500A allows for the vertical 532A or horizontal 532B positioning of a sensor 534A or 534B. The sensor 534A, 543B may be placed within or substantially within the sensor void 502A or 502B. The sensor 534A, 534B can be any sensor capable of detecting, determining, or calculating a magnetic flux or magnetic field. In at least one embodiment, the sensor is a Hall effect sensor.

One possible advantage of the magnetic detection system 500A is the ability to place the sensor 534A, 534B a specified distance away from the sets of magnets 510, 511. The sets of magnets 510, 511 may be arranged around a rotational platform 520, which can rotate about a central axis 522. As would be understood, the sets of magnets 510, 511 generate a magnetic flux or field that surrounds them based on the strength of the magnetic flux or field. The sensor(s) 534A, 534B measurements may be affected based on its proximity to the sets of magnets 510, 511. Thus, the collectors 504 allow for the sensor(s) 5345A, 534B to be placed away from or distal from the sets of magnets 510, 511 to allow for more sensitive and accurate measurement of the magnetic flux or field.

The angle 536 can be created as part of the collector 504. The angle 536 while illustrated as a substantially right angle, could also be any angle desired by a designer, or for a specified design to allow for the placement of a sensor 534A, 534B in any number of specified locations. The angle 536 may allow for the collector 504 to be utilized in a multitude of positions and commercial applications.

FIG. 5B is a side view illustration of a magnetic detection system 500B. The magnetic detection system 500B allows for the positioning 532 of a sensor 534. The sensor 534 may be placed within or substantially within the sensor void 502. The sensor 534 can be any sensor capable of detecting, determining, or calculating a magnetic flux or magnetic field. In at least one embodiment, the sensor is a Hall effect sensor.

One possible advantage of the magnetic detection system 500B is the ability to place the sensor 534 a specified distance away from the sets of magnets 510, 511. The sets of magnets 510, 511 may be arranged around a rotational platform 520, which can rotate about a central axis 522. As would be understood, the sets of magnets 510, 511 generate a magnetic flux or field that surrounds them based on the strength of the magnetic flux or field. The sensor 534 measurements may be affected based on its proximity to the sets of magnets 510, 511. Thus, the collectors 504A, 504B, and 504C (collectively, collectors 504) allow for the sensor 534 to be placed away from or distal to the sets of magnets 510, 511 to allow for more sensitive and accurate measurement of the magnetic flux or field.

For example, the collectors 504A, 504B, and 504C are arranged in a vertical configuration. The vertical configuration allows for the sensor 534 to be horizontally offset from a magnetic source 538. In at least one embodiment, the magnetic source 538 includes two sets of magnets 510, 511. The sets of magnets 510, 511 can be arranged in matched pairs of magnets that are organized with a first set of magnets having north poles facing outward and a second set of magnets having south poles facing outward.

The collectors 504A, 504B, and 504C can be their respective collection points 508A, 508B, and 509 on three different levels 540A, 540B, and 540C that are separated in the vertical direction by a design specific distance. In at least one example, collector 504A is on the same level 540A as the sensor void 502, while collector 504B is on a second level 540B that is separated by a first distance 542A from the first level 540A and the level having the sensor void 502, and collector 504C is on a second level 540C that is separated by a second distance 542B from the first level 540A and the level having the sensor void 502. It would be understood that based on the flow of a magnetic flux or field through the collectors 504 and the length of the collectors 504, there may be a need for additional collection points on one or more of the collectors 504 to account for possible strength or magnitude losses. For example, collector 504C may have additional collection points to maintain the magnetic flux or field ratio for the magnitude or strength of the magnetic flux or field collected by collectors 504A or 504B.

Further to this example, consider that collectors 504A and 504C are partially aligned with a set of magnets 510 that have a north pole facing outward. Collector 504B is aligned with a set of magnets 511 that have a south pole facing outward. The magnetic flux or field ratio for the collectors 504A and 504C is one half (½). However, due to the distance from the collection points 508B of collector 504C to the set of sensor points 507C, there is a loss of approximately five (5) percent of the magnetic flux, but if the number of collection points 508B is increased by two, then the loss may be accounted for and maintain the same magnitude or strength of magnetic flux or field as collector 504A. It would be understood that the numbers described in this example are illustrative, as the percentages and number of collectors may be modified as specified by the design of the magnetic detection system 500B.

FIG. 6A is a top view illustration of a magnet array 650A. The magnet array 650A may have sets of magnets 610A, 610B, 610C, and 611A, 611B that are arranged with respect to a magnetic core 601. The first set of magnets 610A, 610B, 610C (collectively magnets 510) are arranged with the north pole of the magnets 610 facing away from the magnetic core 601. While the second set of magnets 611A, 611B (collectively magnets 611) are arranged with the south pole of the magnets 611 facing away from the magnetic core 601. An air gap 656 may also be found between the sets of magnets 510, 511 or between individual magnets. The air gap 656 may alternatively be a ferrous metal, or non-magnetically permeable material that insulates the sets of magnets 610, 611 from one another.

The magnetic fields 652A, 652B, 652C, 652D (collectively magnetic fields 652) and magnetic fields 654A, 654B, 6543C, 654D (collectively magnetic fields 654) allow for the transfer of magnetic flux and fields to other magnetically permeable materials, or magnetic cores. The magnetic fields 652, 654 will travel from the north pole of a magnet to a south pole of a corresponding magnet. If there is no insulating material or air gap 656, then a magnetic field may travel from the north pole of a magnet to the south pole of the same magnet.

FIG. 6B is a top view illustration of a magnet array 650B. The magnet array 650B can be a Halbach array that is an alternative arrangement of sets of magnets that interact with a magnetic core 601. A Halbach array allows for an increase in the magnetic field in a specific direction without the use of an air gap, or insulation for adjacent magnets. One potential advantage of a Halbach array is the ability to increase the magnitude or strength of magnetic flux or field generated by the magnets. The increased magnitude or strength is facilitated by the unique placement of the magnets in a T shape, or cross shape. The T or cross shape is created by having a vertical magnet 660 having a north pole 661A and a south pole 661B, which is magnetically engaged with two horizontal magnets 662A and 662B with north poles 663A and south poles 663B. In this example, when the north pole 661A is facing upward, the north poles 663A of the horizontal magnets 662A, 662B face towards the vertical magnet 660. It would be understood that the reverse could also be true where the south pole 661B is facing upwards and the south poles 663B of the horizontal magnets 662A, 662B are facing towards the vertical magnet 660.

In this arrangement, there can be a north pole section 666A and a south pole section 666B (collectively sections 666). The two sections 666 visually in this example split a horizontal magnet 662B. The sections 666 allow for magnetic fields 652A, 652B, 652C, and 652D (collectively, magnetic fields 652), and magnetic fields 654A, 654B, 654C, 654D, 654E, and 654F (collectively, magnetic fields 654), with the magnetic fields 652 being from the north section 666A and extend to south sections 666B. The magnetic fields 654 are found near the magnetic core 601 and anywhere there is a north pole and a south pole next to one another.

For example, magnetic fields 654A and 654B move from the north pole section 666A to the adjacent south pole section 666B. Similarly, another north pole section also has a portion of magnetic field 654C that is received by the south pole section 666B. In at least one example, each north pole section 666A can have two magnetic fields 654A and 654B (or magnetic field sections) that emanate from it, and each south pole section 666B receives two magnetic fields 654B and 654C (or magnetic field sections) that emanate from north pole sections. It would be understood that other configurations or arrangements of magnets may also be utilized.

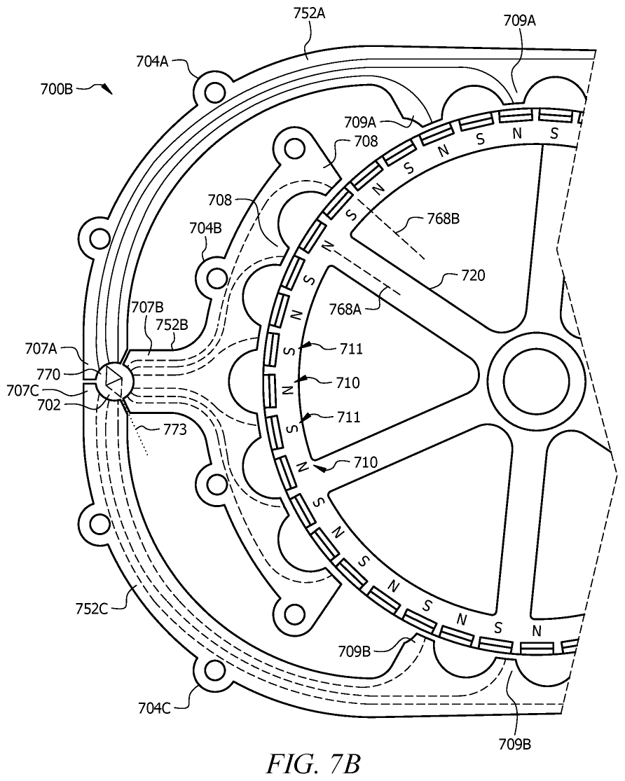

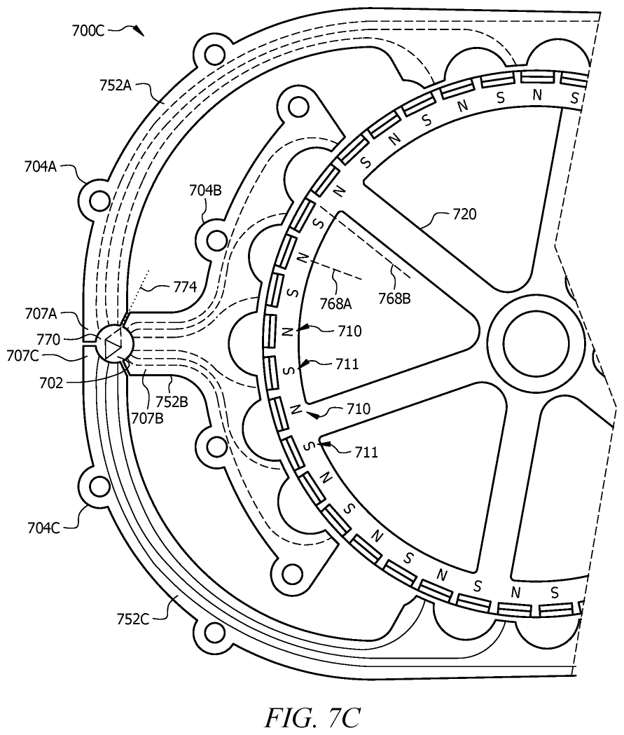

FIG. 7A is a top view illustration of a magnetic field detection system 700 with a rotating platform 720 in a first position 768A. With reference to FIGS. 7A, 7B, and 7C, but in particular, FIG. 7A, the rotating platform 720 may have two or more sets of magnets 710 (north pole orientated outward) and 711 (south pole orientated outward) along the outer circumference of the rotating platform 720. The sets of magnets 710, 711 by their very nature generate a magnetic field or flux from their north poles and moves toward a south pole.

The magnetic field lines 752A, 752B, and 752C (collectively magnetic field lines 752) are the result of a transfer of magnetic flux from the set of magnets 710 to a collector 704B. The collector 704B has at a first end a set of collection points 708A, 708B, 708C, 708D, 708E, and 708F (collectively, collection points 708) that are distal from a second end having at least one sensor point 707B. The magnetic field line 752B can be considered a north magnetic field as the collection points 708 are one hundred (100) percent or fully aligned with the set of magnets 710 that have their north pole facing outward from the rotating platform 720. The full alignment is beneficial as the collection points 708 are smaller in width (width being the side facing the set of magnets 710) than the width of the magnets that form the set of magnets 710. By being fully aligned, the collection points 708 can collect a maximum amount of magnetic flux from the set of magnets 710. The magnetic flux and correspondingly the magnetic field line 752B can move from the collection points 708 to the sensor point 707B. The sensor point 707B can be arranged around a sensor void 702. The sensor point 707B may have corresponding sensor points 707A and 707C of the collectors 704A and 704C.

The sensor void 702 can allow for the placement of a sensor (not illustrated). The direction of the magnetic field lines 752 are illustrated by a directional indicator 770 in a first position 772. The magnetic field line 752B contains all of the magnetic flux from the set of magnets 710. The magnetic flux can be transferred to collectors 704A and 704C through the sensor void 702. The magnetic flux may be split between the two collectors 704A and 704B from the collector 704B. As seen the magnetic field lines 752A and 752C equal the number of magnetic field lines 752B. The reason for the split between the two collectors 704A and 704C is the offset of the collection points 709A and 709B from the set of magnets 711. The collection points 709A and 709B are positioned in a manner that one half of the width of the collection points 709A and 709B is aligned with the set of magnets 711. Because only one half of the width of the collection points 709A and 709B is aligned with the set of magnets 711, only one half of the magnetic flux can be transferred to the set of magnets 711 from each collector 704A and 704C. Thus, the magnetic flux collected by collector 704B is equal to the amount of magnetic flux transferred from collectors 704A and 704C. As the rotating platform 720 is rotated, the magnetic flux shifts as illustrated in FIGS. 7B and 7C.

FIG. 7B is a top view illustration of a magnetic field detection system 700 with a rotating platform 720 in a second position 768B. With reference to FIGS. 7A, 7B, and 7C, but in particular FIG. 7B, the rotating platform 720 can be rotated about a central axis (not shown). When the rotated from a first position 768A (illustrated in FIG. 7A) to a second position 768B, the alignment of the collection points 708, 709A, and 709B can be shifted from the respective sets of magnets 710 and 711.

In FIG. 7A, the collection points 708 are fully aligned with the set of magnets 710, while in FIG. 7B, the collection points 708 are partially aligned with the set of magnets 711. Similarly, the collection points 709A, while partially aligned with the set of magnets 711 in FIG. 7A, after rotation of the rotating platform 720 to the second position 768B the collection points 709A are fully aligned with the set of magnets 710. The collection points 709B remain partially aligned with the set of magnets 711 in both the first position 768A (seen in FIG. 7A) and in the second position 768B. However, the portion of the set of magnets 711 with which the collection points 709B are partially aligned is shifted from the first position 768A to the second position 768B.

These changes in alignments of the collection points 708, 709A, and 709B with the respective sets of magnets 710, 711 allow for magnetic field lines 752 to shift. Because the respective collection points 708, 709A, and 709B are realigned based on the position of the rotating platform 720 and the respective sets of magnets 710, 711, the magnetic field orientation measured in the sensor void 702 shifts. The orientation shift is shown by the directional indicator 770 in a second position 773. The shift of the directional indicator 770 is a multiple of the rotation of the rotating platform. For example, the collectors 704 may allow for a twenty times multiplication of the measurable magnetic field or flux. This can be further seen as the directional indicator 770 may complete twenty full rotations for one full rotation of the rotating platform 720.

FIG. 7C is a top view illustration of a magnetic field detection system 700 with a rotating platform 720 in a third position 768C. With reference to FIGS. 7A, 7B, and 7C, but in particular, FIG. 7C, the third position 768C provides a visual representation of the changes in the magnetic field lines 752 as the rotating platform 720 is moved from the first position 768A (FIG. 7A), to the second position 768B (FIG. 7B), and now a third position 768C. The third position 774 of the directional indicator 770 illustrates the change in magnetic field or flux that a sensor may detect within the sensor void 702. As described above, a multiplicative effect of the measurable magnetic flux allows for an increase in the sensitivity of a sensor for determining the magnetic field or flux.

An example of how the collectors 704 can be used for increased sensitivity of a sensor is in the field of robotics. For example, when used in a robotics application, the collectors 704 in combination with a sensor can allow for the detection of small shifts of a robotic arm. Based on the number of collection points for each collector, and the number of collection points, the mathematical relationship can be programed into a computing device that provides control of other robotic systems or sensors. As the rotating platform 720, which could be a robotic arm, wheel, or other moveable object, is moved or rotated, the magnetic flux or field captured or collected by the collectors 704 changes as well. As shown in FIGS. 7A, 7B, and 7C even small shifts in rotating platform 720 can cause large shifts in the magnetic field or flux, as shown by the magnetic field lines 752.

It would be noted that the collectors, while shown with no insulating material, could have insulating material on different surfaces to prevent magnetic flux or the generated magnetic field from being received by or transmitted to other collectors. Additionally, any insulating material may also allow for a magnification of the magnetic flux or field within a collector as it can assist in reducing magnetic losses.

While this disclosure has been particularly shown and described with reference to preferred embodiments, it will be understood by those skilled in the art that various changes in form and detail may be made therein without departing from the spirit and scope of the invention. The inventors expect skilled artisans to employ such variations as appropriate, and the inventors intend the invention to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

While various embodiments in accordance with the principles disclosed herein have been described above, it should be understood that they have been presented by way of example only, and not limitation. Thus, the breadth and scope of this disclosure should not be limited by any of the above-described exemplary embodiments but should be defined only in accordance with any claims and their equivalents issuing from this disclosure. Furthermore, the above advantages and features are provided in described embodiments but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, and by way of example, although the headings refer to a “Technical Field,” the claims should not be limited by the language chosen under this heading to describe the so-called field. Further, a description of a technology as background information is not to be construed as an admission that certain technology is prior art to any embodiment(s) in this disclosure. Neither is the “Brief Summary” to be considered as a characterization of the embodiment(s) set forth in issued claims. Furthermore, any reference in this disclosure to “invention” in the singular should not be used to argue that there is only a single point of novelty in this disclosure. Multiple embodiments may be set forth according to the limitations of the multiple claims issuing from this disclosure, and such claims accordingly define the embodiment(s), and their equivalents, that are protected thereby. In all instances, the scope of such claims shall be considered on their own merits in light of this disclosure but should not be constrained by the headings set forth herein.

I claim:

1. A magnetic field detection system comprising:
a first collector having a set of first collection points configured to interact with a set of magnets and a first sensor point; wherein the set of first collection points is configured to receive a first fraction of a magnetic flux generated by the set of magnets;
a second collector having a set of second collection points configured to interact with the set of magnets and a second sensor point; wherein the set of second collection points is configured to receive a second fraction of the magnetic flux generated by the set of magnets;
a third collector having a set of third collection points configured to interact with the set of magnets and a third sensor point; wherein the set of third collection points transmits a sum of the first fraction and the second fraction of the magnetic flux to the set of magnets; and
wherein the first fraction of the magnetic flux, and the second fraction of the magnetic flux pass from the first sensor point and the second sensor point through a sensor detection area to the third sensor point.

2. The magnetic field detection system of claim 1, wherein the first collector interacts with a first portion of the set of magnets.

3. The magnetic field detection system of claim 1, wherein the second collector interacts with a first portion of the set of magnets.

4. The magnetic field detection system of claim 1, wherein the third collector interacts with a first portion of the set of magnets.

5. The magnetic field detection system of claim 1, wherein the first collector interacts with a first portion of the set of magnets, the second collector interacts with a second portion of the set of magnets, and the third collector interacts with a third portion of the set of magnets.

6. The magnetic field detection system of claim 1, wherein the set of magnets are movable in relation to the set of first collection points, the set of second collection points, and the set of third collection points.

7. The magnetic field detection system of claim 1, wherein when the set of magnets move in relation to the set of first collection points, the set of second collection points, and the set of third collection points, an amount of the first fraction of the magnetic flux and an amount of the second fraction of the magnetic flux are modified according to the movement of the set of magnets.

8. The magnetic field detection system of claim 1, wherein the first sensor point, the second sensor point, and the third sensor point can interact with a magnetic flux sensor.

9. The magnetic field detection system of claim 1, wherein the set of magnets further comprises pairs of magnets, wherein each pair has a north pole and south pole, and the number of magnets within the set of magnets determines the sensitivity of the magnetic field detection system.

10. A magnetic field detection system comprising:
a first collector having a set of first collection points along a first edge of the first collector, and a first sensor point on a second edge of the first collector that is distal from the first edge of the first collector;
a second collector having a set of second collection points along a first edge of the second collector, and a second sensor point on a second edge of the second collector that is distal from the first edge of the second collector;
a third collector having a set of third collection points along a first edge of the third collector, and a third sensor point on a second edge of the third collector that is distal from the first edge of the third collector; and
wherein said sensor points are equally spaced around a sensor void that is defined by the arrangement of said sensor points.

11. The magnetic field detection system of claim 10, wherein the first collector is made of a magnetically permeable material.

12. The magnetic field detection system of claim 10, wherein the second collector is made of a magnetically permeable material.

13. The magnetic field detection system of claim 10, wherein the third collector is made of a magnetically permeable material.

14. The magnetic field detection system of claim 10, wherein the set of first collection points are equally spaced along the first edge of the first collector.

15. The magnetic field detection system of claim 10, wherein the set of second collection points are equally spaced along the first edge of the second collector.

16. The magnetic field detection system of claim 10, wherein the set of third collection points are equally spaced along the first edge of the third collector.

17. The magnetic field detection system of claim 10, wherein the first sensor point, the second sensor point, and the third sensor point do not touch one another when defining the sensor void.

18. The magnetic field detection system of claim 10, further comprising a sensor placed in close proximity of the sensor void for the detection of a magnetic field.

19. A magnetic field detection system comprising:
a first collector having a set of first collection points along a first edge of the first collector configured to interact with a set of magnets and a first sensor point on a second edge of the first collector that is distal from the first edge of the first collector;
wherein the set of first collection points is configured to receive a first fraction of a magnetic flux generated by the set of magnets;
a second collector having a set of second collection points along a first edge of the second collector configured to interact with the set of magnets and a second sensor point on a second edge of the second collector that is distal from the first edge of the second collector; wherein the set of second collection points is configured to receive a second fraction of the magnetic flux generated by the set of magnets;
a third collector having a set of third collection points along a first edge of the third collector configured to interact with the set of magnets and a third sensor point on a second edge of the third collector that is distal from the first edge of the third collector; wherein the set of third collection points transmits a sum of the first fraction and the second fraction of the magnetic flux to the set of magnets;
wherein said sensor points are equally spaced around a sensor void that is defined by the arrangement of said sensor points; and
wherein the first fraction of the magnetic flux, and the second fraction of the magnetic flux pass from the first sensor point and the second sensor point through a sensor detection area to the third sensor point.

20. The magnetic field detection system of claim 19, further comprising:
a sensor placed in close proximity of the sensor void for the detection of a magnetic field;
wherein the first collector interacts with a first portion of the set of magnets, the second collector interacts with a second portion of the set of magnets, the third collector interacts with a third portion of the set of magnets as detected by the sensor;
wherein the detection by the sensor occurs because the first collector, second collector, and third collector are made of magnetically permeable materials; and
the set of magnets further comprises pairs of magnets and each magnet pair has a north pole and south pole, and the number of magnets within the set of magnets determines the sensitivity of the magnetic field detection system.
